(19) United States
(12) Patent Application Publication
(10) Pub. No.: US 2019/0338747 A1
(43) Pub. Date: Nov. 7, 2019

(54) FAIL/SAFE SYSTEM FOR MACHINE POWER GENERATOR

(71) Applicant: Ernest William Townsend, IV, Scottsdale, AZ (US)

(72) Inventor: Ernest William Townsend, IV, Scottsdale, AZ (US)

(21) Appl. No.: 16/396,412

(22) Filed: Apr. 26, 2019

Related U.S. Application Data
(60) Provisional application No. 62/665,371, filed on May 1, 2018.

(51) Int. Cl. F03B 17/02; H03K 5/156; F03G 6/02; F16K 21/18

(52) U.S. Cl. CPC F03B 17/025; F16K 21/18; F03G 6/02; H03K 5/1565

(57) ABSTRACT

In accordance with the present invention a start/stop system is provided for a machine that drives an electric generator by moving buoyant modules on a duty-cycle pathway through a bi-level water tank. Included is a valve mechanism that maintains different water surface levels in the bi-level tank, and also establishes different spaces within the bi-level tank. Additionally, grips are included for selectively holding individual modules in respective spaces. To stop the machine, water is drained from the bi-level tank, and grips are activated, to hold modules in their respective spaces. To restart, water is introduced into the spaces and the grips are deactivated to release the modules for operation.

This application claims the benefit of U.S. Provisional Patent Application Ser. No. 62/665,371, filed May 1, 2018. The entire contents of Application Ser. No. 62/665,371 are hereby incorporated by reference herein.

### FIELD OF THE INVENTION

The present invention pertains generally to water tanks which are used to propel submerged buoyant modules along a duty-cycle pathway through a tank for the purpose of operating a machine that drives an electric generator. More particularly, the present invention pertains to tanks that include systems for selectively draining water from the tanks for operational safety or maintenance purposes. The present invention is particularly, but not exclusively, useful as a start/stop system for water tanks wherein buoyant modules are decelerated after falling under the influence of gravity into the tank, and are then accelerated by buoyancy for ejection from the tank.

### BACKGROUND OF THE INVENTION

All machines require periodic maintenance. Typically, maintenance is performed while the machine is not in operation. There are, however, some machines, such as those that drive electric power generators, for which a continuous uninterrupted operation is desired. Nevertheless, it is realistic to still expect that circumstances can arise for even continuously operating machines when shutting down the machine becomes necessary.

Of particular concern when shutting down and starting up machines, such as envisioned for the present invention, are issues that involve how to handle huge moving components that may be travelling at substantial speed. Such is the case for the present invention.

In accordance with the present invention, a machine duty cycle operates by shuttling modules on a power/return (duty-cycle) pathway. On a power portion of the duty-cycle pathway, starting at zero velocity, the modules are sequentially dropped from a same start point. As a module falls under the influence of gravity, it engages with a generator to generate electric power. After generating power, the module enters a bi-level water tank where it is first decelerated to zero velocity. The module is then reoriented onto a return portion and, as it remains submerged, the module is moved under the influence of its buoyancy back up to its start point for the beginning of a subsequent duty cycle.

With the above in mind, it is an object of the present invention to provide a system for stopping a machine which operates by moving buoyant modules through a liquid medium. Another object of the present invention is to provide a start/stop system for machines which incorporate buoyant modules that are decelerated after falling under the influence of gravity into a water tank, and are then accelerated by buoyancy for ejection from the tank. Still another object of the present invention is to provide a system for stopping/starting a machine that operates by moving buoyant modules through a liquid medium, which is easy to use, relatively simple to manufacture, and comparatively cost effective.

### SUMMARY OF THE INVENTION

A system and method are provided by the present invention which will voluntarily or involuntarily shut down a machine that drives a linear power generator. In particular, the machine includes a bi-level liquid filled tank that sequentially cycles a plurality of modules through their respective duty cycles on the machine. In the event there is a need to stop an operation of the machine, the present invention is provided to arrest modules at predetermined locations in their respective duty cycles.

During a duty cycle, a module is initially dropped from a launch gantry. While dropping, the module engages with the linear power generator. With this engagement, kinetic energy of the falling module is converted into electric energy by the linear power generator. For the remainder of its duty cycle, the module is returned by buoyancy on a portion of a duty-cycle pathway that passes through the bi-level tank and back up to the launch gantry. For the special case wherein a continuous operation of the machine is required, it will be necessary for at least one module to be engaged with the linear power generator at all times. Otherwise, capacitors may be used to temporarily store electrical energy that has been pre-generated during episodes of module non-engagement with the linear generator.

Due to frequent changes in velocity, it is important to recognize that in a complete duty cycle each module follows a specific velocity/location profile. As envisioned for the present invention, this velocity/location profile is the same for each module, and it is invariable from one duty cycle to the next. A consequence here is that when the location of one module is determined, the various locations of all other modules in the machine can also be determined.

With the above in mind, and by way of example, consider a machine operation with four modules. In this operation, it is envisioned that one module will always be engaged with the linear power generator. Timewise, this means each module spends ¼ of its duty cycle time generating power with the linear power generator. The remaining ¾ of its duty cycle time is spent returning the module to the launch gantry for another duty cycle. Thus, in this example at least three modules are always interacting directly with the bi-level tank.

Continuing with the four module example, a start/stop operation for the present invention must account for all four modules. This is so, regardless whether the module is engaged with the linear power generator, or is being returned via the bi-level tank to the launch gantry. Importantly, the present invention envisions that when the machine is stopped, none of the modules will remain engaged with the linear power generator. Accordingly, a module may be arrested either on the gantry or in the bi-level tank.

Structurally, the bi-level tank includes a transfer tank that is in fluid communication with a return tank that extends vertically from the transfer tank. In this configuration, a transfer port is provided that separates the return tank from the transfer tank and an access port is provided that allows modules access into the transfer tank. Importantly, a valve mechanism is provided that simultaneously opens/closes (closes/opens) the access port and the transfer port. N.B. the access port and the transfer port can never be open at the same time. Consequently, relative to the always exposed higher liquid surface level for the return tank, a lower liquid surface level for the transfer tank must be maintained by the valve mechanism.

The bi-level tank may also include a stop-valve unit. Specifically, for this example, a stop-valve unit is located in the return tank between its higher liquid surface level, and the transfer port at the bottom of the return tank. For the specific portion of the duty-cycle pathway whereon modules are returned to the launch gantry through the bi-level tank, the bi-level tank can be considered as four separate sections. From higher to lower, these sections include: i) the launch gantry, ii) an upper return tank, iii) a lower return tank, and iv) the transfer tank. For purposes of this disclosure, these sections are operationally considered below in the order set forth above.

Whenever a STOP order is voluntarily or involuntarily given, the transfer valve between the lower return tank and the transfer tank will be closed (consequently, the access port into the transfer tank will be opened). At the same time, the stop-valve unit between the upper return tank and the lower return tank is activated to establish a liquid tight seal between the upper and lower return tanks. Simultaneously, when the stop-valve is activated, liquid drains that are respectively located in the upper return tank above the stop-valve and in the lower return tank above the transfer valve, as well as an air vent immediately below the stop-valve are all opened. Thus, water is allowed to drain simultaneously from both the upper and lower return tanks. Also, water can be drained, if desired, from a master drain that is located near the bottom of the transfer tank.

The consequence of the above actions taken by the machine allow one module to be held by the launch gantry. The second in-line module will be lowered into and held by a grip at the bottom of the upper return tank as water is drained from the upper return tank. Likewise, the third in-line module will be lowered and held by a grip at the bottom of the lower return tank as water is drained from the lower return tank. Also, the fourth module in the system will disengage from the linear power generator and will enter the transfer tank. After it decelerates in the transfer tank, the fourth module will be held by a grip in the transfer tank.

In accordance with the above disclosure, a process is provided whereby all modules can be arrested in the machine. Once they have been arrested, the modules will remain stationary either on the launch gantry or in the bi-level tank. A logic chart for computer implementation of the steps to be taken to accomplish this is also provided for the present invention.

An important feature of the present invention is that, once the machine has been stopped, the first step for a restart is to refill the upper and lower return tanks with liquid (water). Also, the transfer tank can be refilled, if necessary. Each module can then be sequentially released for compliance with their respective velocity/location profile.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a cross section view of a bi-level tank for the machine of the present invention showing locations for velocity sensors in the bi-level tank, as well as locations for the valves, the grips and the drains required for a stop/start operation of the machine;

FIG. 2 is a velocity/location profile (not to scale) for a module of the present invention, showing the velocity variations of a module as it moves through the machine during a duty cycle;

FIG. 3A is a representative depiction of the respective velocity/location conditions for four separate modules, contemporaneously presented during their duty cycles, with one module being located between a launch gantry that is positioned above the bi-level tank and an access port that provides for module entry into the bi-level tank;

FIG. 3B is a depiction of the velocity/location conditions of all four modules shown in FIG. 3A, in their inactive (zero velocity) state following an order to STOP the machine;

FIG. 3C is a depiction of the modules shown in FIG. 3A with two modules being located between the launch gantry and the access port at the time a STOP order is given, together with the successive transition of all modules through the conditions of FIG. 3A and then into their inactive states shown in FIG. 3B; and

FIG. 4 is a logic flow chart showing the steps taken during a shutdown of the machine in response to a STOP order.

### DESCRIPTION OF THE PREFERRED EMBODIMENTS

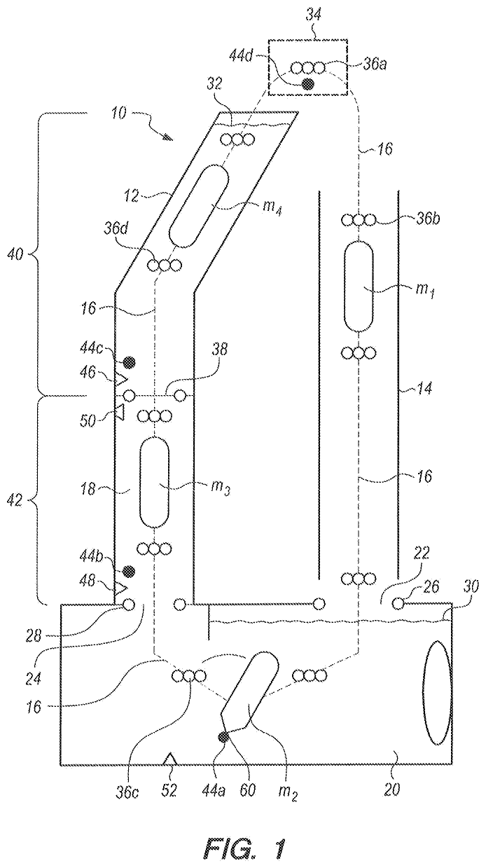

Referring initially to FIG. 1, a machine in accordance with the present invention is shown and is generally designated 10. As shown, the machine 10 includes a bi-level tank 12 which interacts with a linear electric generator 14. Together, the bi-level tank 12 and the linear electric generator 14 define a closed duty-cycle pathway 16. As intended for the present invention, a plurality of an n number of modules m₍₁₋ₙ₎ are simultaneously propelled along the duty-cycle pathway 16. For a continuous operation of the linear electric generator 14, at least one module mₙ needs to be engaged with the linear electric generator 14 all of the time. For the purposes of this disclosure, the number of modules mₙ that are incorporated into the machine 10 will be four (n=4). Thus, only four modules, m₁, m₂, m₃, and m₄, have been identified to describe the machine 10.

In FIG. 1 it is also seen that the bi-level tank 12 includes both a return tank 18 and a transfer tank 20. Further, the return tank 18 has an access port 22 which provides each module mₙ individual access into the bi-level tank 12. Also, a transfer port 24 is provided to separate the return tank 18 from the transfer tank 20. A valve mechanism that includes an access valve 26 and a transfer valve 28 are incorporated in the machine 10 for the purposes of respectively opening and closing the access port 22 and the transfer port 24.

The general purpose for the valve mechanism of machine 10 is three-fold. One purpose is to provide sequential access for individual modules mₙ into the transfer tank 20 through the access port 22. Another, is to maintain a height differential between a lower surface level 30 in the transfer tank 20 and an upper surface level 32 in the return tank 18 during the operation of machine 10. And, another is to establish an unobstructed portion of the duty-cycle pathway 16 through the bi-level tank 12 from the lower surface level 30 in the transfer tank 20 to the upper surface level 32 in the return tank 18. Importantly, for an operation of the machine 10, the access port 22 and the transfer port 24 can never be open at the same time.

Additional features of the machine 10 include a launch gantry 34 that is positioned above the bi-level tank 12 to initiate the travel of each module mₙ along the duty-cycle pathway 16. Most importantly, during its duty cycle each module mₙ engages with the linear electric generator 14. The launch gantry 34 also arrests each module mₙ after it has completed one duty cycle and is ready to begin another.

Another important feature of the machine 10 is the plurality of velocity sensors 36 that are prepositioned at selected locations along the duty-cycle pathway 16. For purposes of disclosure, only four velocity sensors 36a-d have been specifically designated. In particular, the sensor 36a is shown located at the launch gantry 34, the sensor 36b is shown located on the linear electric generator 14, the sensor 36c is shown located in the transfer tank 20, and the sensor 36d is shown located in the return tank 18. As will become more apparent with the additional disclosure below, it is important that the velocity and location of each module mₙ are continuously monitored as they pass along the duty-cycle pathway 16.

As intended for the present invention, whenever the machine 10 is stopped, either voluntarily or involuntarily, it is necessary to individually isolate each module mₙ. In order to accomplish this module isolation for a four-module machine 10, a stop-valve unit 38 is mounted in the return tank 18, as shown in FIG. 1. The result here is that the return tank 18 is bifurcated into an upper return tank 40, and a lower return tank 42. Further, a plurality of grips 44 are mounted on the machine 10 to hold each module mₙ in isolation during a stoppage of the machine 10. When stoppage happens for an exemplary four-module machine 10, one module mₙ will be held by a grip 44a in the transfer tank 20. Another module mₙ will be held by a grip 44b in the lower return tank 42 near the transfer valve 28. Still another module mₙ will be held by a grip 44c in the upper return tank 40 (above the stop valve unit 38). And, another module mₙ will be held on the launch gantry 34 by a grip 44d. As envisioned for the present invention, the grips 44 can be of a type that are well known in the pertinent art, such as a mechanical grip or a magnetic grip that will function for the purposes disclosed above.

It is to be appreciated that whenever a machine 10 is stopped, it is necessary to activate (i.e. close) the stop-valve unit 38, to close the transfer valve 28 (which also opens the access valve 26), and to drain water (liquid) from both the upper return tank 40 and the lower return tank 42. To do this, a drain 46 is provided above the stop valve unit 38 to remove water from the upper return tank 40. Once the upper return tank 40 has been drained, the grip 44c which is associated with the drain 46 will hold the module mₙ that was in the upper return tank 40 at the time the machine 10 was stopped. Additionally, a drain 48 is provided above the transfer valve 28, and a vent 50 is positioned immediately below the stop valve unit 38 to allow for the removal of water from the lower return tank 42. In this case the grip 44b will hold the module mₙ that was in the lower return tank 42 at the time the machine 10 was stopped.

At the same time when modules mₙ and m_{n±1} have been arrested and are being respectively held in the upper return tank 40 and the lower return tank 42, another module mₙ can be held by the grip 44d on the launch gantry 34. Also, an additional feature of the machine 10 is the provision for a master drain 52 at the bottom of the transfer tank 20. Specifically, whenever a machine 10 has been stopped, because the access port 22 will be open, the master drain 52 can be opened to drain water from the transfer tank 20. When this is done, the fourth module mₙ can be arrested and held by the grip 44a in the transfer tank 20.

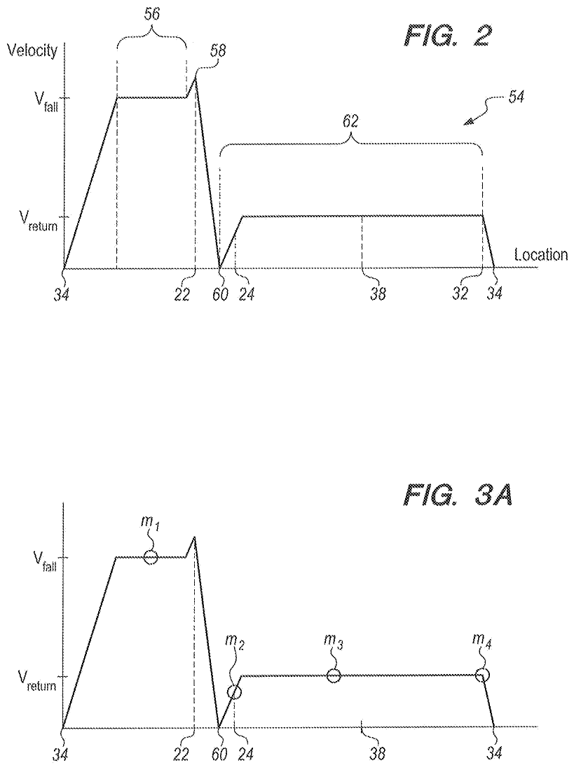

Turning now to FIG. 2, a velocity/location profile for the duty cycle of a module mₙ is shown and is generally designated 54. An important consideration for the machine 10 is that the velocity/location profile 54 will be the same for each module mₙ. Also, the same velocity/location profile 54 will be continuously repeated for each module mₙ, for each duty cycle. A particular feature of the velocity/location profile 54 that is of utmost importance for the present invention is the time segment 56. Specifically, the time segment 56 represents a time duration that corresponds to the time a module mₙ is engaged with the linear electric generator 14 to generate electric power. With reference to FIG. 2, it will be seen that the time segment 56 begins after a module mₙ has left the launch gantry 34 and has attained a velocity V_{fall} for engagement with the linear electric generator 14. V_{fall} is then maintained constant during the engagement of the module mₙ with the linear electric generator 14.

Upon disengagement of the module mₙ from the linear electric generator 14 at the end of time segment 56, the module mₙ will accelerate, to a slightly higher velocity at point 58 on the velocity/location profile 54. At this time, the module mₙ passes through the access port 22 and enters the transfer tank 20. Once in the transfer tank 20, the now submerged module mₙ decelerates to zero velocity at the point 60. From point 60, the module mₙ accelerates through the transfer port 24 to a terminal velocity Vᵣₑₜᵤᵣₙ which is maintained thereafter during a buoyancy segment 62 of the velocity/location profile 54. The buoyancy segment 62 then ends when the module mₙ breaches the upper surface level 32 and returns to the launch gantry 34.

Important engineering considerations for the duty cycle of a module mₙ involves its design. In particular, the module mₙ must be hydrodynamically designed to decelerate to zero velocity in the transfer tank 20 as quickly as possible. On the other hand, it must then attain and maintain a terminal velocity Vᵣₑₜᵤᵣₙ during the buoyancy segment 62 that is sufficient to breach the upper surface level 32 for its return to the launch gantry 34.

As noted above, in order for the machine 10 to provide a continuous source of substantially constant electric power it is necessary for one module mₙ to be engaged with the linear power generator 14 at all times. It then follows that the duration of a duty cycle for each module mₙ in a four-module machine 10 must be exactly four times the duration of the time segment 56. Indeed, time segment 56 will dictate many structural and functional design considerations for the machine 10. These include: dimensions for the bi-level tank 12; a time schedule for the operation of the valve mechanism (i.e. access valve 26 and transfer valve 28); and the time for executing a STOP order that will most effectively shut down the machine 10 in accordance with the present invention.

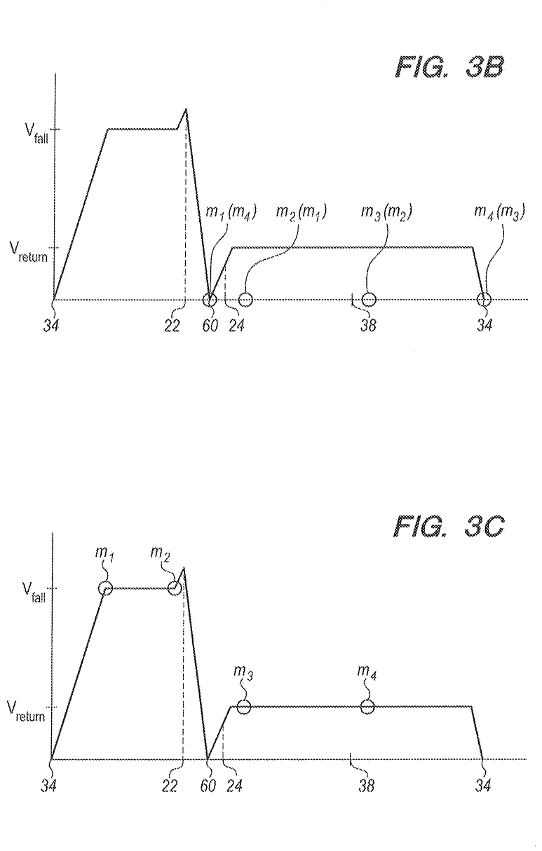

The consequence of executing a STOP order for the machine 10 will be best appreciated with collective reference to FIGS. 3A, 3B and 3C. These Figs. are properly considered over a time sequence wherein FIG. 3A shows the modules m_{(1 through 4)} at arbitrary locations along the velocity/location profile 54 for the machine 10 when a STOP order is initially given. FIG. 3B shows the location of modules m_{(1 through 4)} when water has been drained from the bi-level tank 12 and the machine 10 has stopped. After the machine 10 has been determined to be operable, the machine 10 can then be restarted. Initially, the bi-level tank 12 must be refilled with water. A time sequence for releasing the grips 44a-d with a coordinated activation of the stop-valve unit 38, the valve mechanism (access valve 26 and transfer valve 28) and the operation of the launch gantry 34 will depend on dimensions of the particular machine 10.

During an operation of the machine 10, FIG. 3C shows all four modules m_{(1 through 4)} at a same time on their respective duty cycles. In particular, FIG. 3C shows module m₁ being engaged with the linear electric generator 14 as the module m₂ disengages from the linear electric generator 14 for entry into the bi-level tank 12. The modules mₙ then resume continuous repetitions of their respective duty cycles until the machine 10 receives the next STOP order.

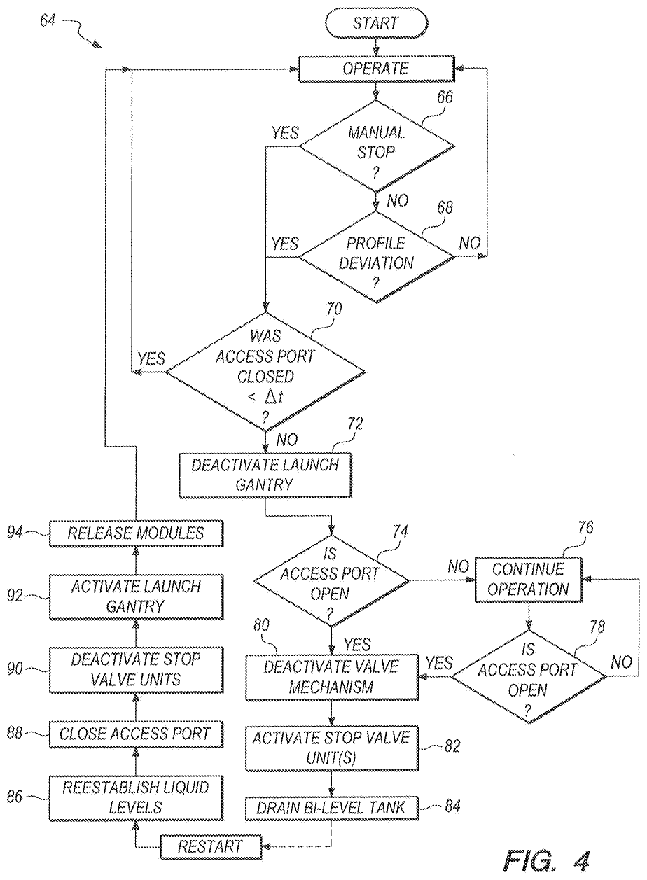

An operational sequence for starting and restarting a machine 10 of the present invention is shown in the logic chart presented in FIG. 4 and generally designated 64. With reference to FIG. 4 it will be appreciated that during an operation of the machine 10 its continued operation is constantly monitored. Specifically, if either a manual STOP order is given (inquiry block 66), or there is an unacceptable deviation in the velocity/location profile 54 of a module mₙ (inquiry block 68), the open/close status of the access port 22 is checked (inquiry block 70). When it is determined that the access port 22 is not closed, i.e. the access port 22 is open, the launch gantry 34 can be deactivated (action block 72).

Confirmation that the access port 22 is indeed open (inquiry block 74), is assured by the combined operation of action block 76 and inquiry block 78. Once an open condition for access port 22 has been checked and assured, a sequence of actions are immediately taken to stop an operation of the machine 10. These actions include: deactivating the valve mechanism (action block 80) to maintain the access port 22 in an open condition and the transfer port 24 is a closed condition. Simultaneously, the stop-valve unit(s) 38, if incorporated, is(are) activated into a closed condition (action block 82), and the bi-level tank 12 is drained (action block 84).

A restart of the machine 10 is accomplished by a predetermined sequence of events which, as implied above, can vary according to the characteristics of each particular machine 10. Stated differently, the sequence of actions presented in logic chart 64 may vary. To initiate a restart of the machine 10, it is first necessary to refill the bi-level tank 12 with water (action block 86). Either before or during the process of refilling the bi-level tank 12 it is also necessary to ensure that the access port 22 has been closed (action block 88), i.e. transfer port 24 is open. Also, during the refilling process, the stop-valve unit 38 needs to be opened (action block 90). With the bi-level tank 12 refilled, the launch gantry 34 can be reactivated (action block 92) and the modules mₙ released (action block 94). As noted above, the actual performance of the various tasks disclosed here can be varied.

While the particular Fail/Safe System for Machine Power Generator as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A system for stopping a machine which operates by moving buoyant modules through a liquid medium, the system comprising:
a plurality of modules;
a bi-level tank having an exposed upper liquid surface level and a sealed/exposed lower liquid surface level, wherein a duty-cycle pathway is established through the machine for each module, with a portion of the duty-cycle pathway passing through the bi-level tank for transit of each module from the lower liquid surface level to the upper liquid surface level of the bi-level tank;
a valve mechanism, including a transfer valve submerged in the bi-level tank to establish a return tank between the transfer valve and the upper liquid surface level and a transfer tank between the transfer valve and the lower liquid surface level, wherein the valve mechanism includes an access valve to expose the lower liquid surface level when the transfer valve is closed and to provide a liquid-tight seal over the lower liquid surface level when the transfer valve is open, wherein, with the transfer valve open, the pathway is unobstructed between the transfer tank and the return tank; and
a drain located in the return tank above the transfer valve, wherein the drain is selectively activated to drain liquid from the return tank and stop the machine when a module is on the pathway in the return tank and the transfer valve has been activated to remain permanently closed.

2. The system of claim 1 wherein the drain is a first drain and the system further comprises a stop-valve unit which comprises:
a stop-valve located in the return tank between the upper liquid surface level and the transfer valve to divide the return tank into an upper return tank above the stop-valve and a lower return tank below the stop-valve, wherein the stop-valve establishes a liquid tight barrier across the pathway in the return tank between the upper return tank and the lower return tank when the stop-valve is activated;
an air vent located below the stop-valve to allow removing liquid from the lower return tank through the first drain when the stop-valve is activated; and
a second drain located in the upper return tank above the stop-valve to allow draining of liquid from the upper return tank when the stop-valve is activated.

3. The system recited in claim 2 wherein each module has a same velocity/location profile along the pathway through the bi-level tank during a duty cycle.

4. The system recited in claim 3 having an n number of modules.

5. The system recited in claim 4 wherein the duty cycle of each module is divided into an n number of sequentially equal time segments, and wherein the n^{th} time segment for a particular module is contiguous with the time segment of an n±1 adjacent module.

6. The system recited in claim 5 wherein each time segment is established to be equal to a time interval wherein a module is engaged with an electric power generator.

7. The system recited in claim 2 further comprising a plurality of grips positioned in the bi-level thank, wherein each grip in the plurality of grips is positioned at a predetermined location in the bi-level tank to hold a module stationary when the grip is activated during a stoppage of the machine.

8. The system recited in claim 7 wherein the grips are deactivated and the transfer valve is opened to release the modules for a resumption of an operation of the machine.

9. The system recited in claim 7 wherein the plurality of grips comprises:
a first grip positioned in the upper return tank above the stop-valve to hold a module in the return tank when the stop-valve is activated;
a second grip positioned in the upper return tank below the stop-valve and above the transfer valve to hold a module in the return tank when the stop-valve is activated; and
a third grip positioned in the transfer tank to hold a module in the transfer tank when the stop-valve is activated.

10. The system recited in claim 2 wherein there is a plurality of stop-valves located in the return tank.

11. The system recited in claim 2 further comprising a master drain located in the transfer tank for removing liquid from the transfer tank.

12. A method for stopping a machine which operates by moving buoyant modules through a liquid medium held in a bi-level tank, wherein the bi-level tank has an exposed upper liquid surface level and a sealed/closed lower liquid surface level, wherein a same, closed, duty-cycle pathway is defined through the machine for each module, the method comprising the steps of:
operating a valve mechanism mounted in the bi-level tank to simultaneously isolate individual modules in selected areas of the bi-level tank in response to a STOP order;
draining liquid from predetermined areas of the bi-level tank; and
holding each module in its respective area of the bi-level tank until operation of the machine can be resumed.

13. The method recited in claim 12 wherein the valve mechanism comprises:
a transfer valve submerged in the bi-level tank to define a return tank between the transfer valve and the upper liquid surface level and to define a transfer tank between the transfer valve and the lower liquid surface level; and
an access valve to expose the lower liquid surface level when the transfer valve is closed and to provide a liquid-tight seal over the lower liquid surface level when the transfer valve is open.

14. The method recited in claim 13 wherein the draining step includes removing liquid from the return tank through a drain located in the return tank above the transfer valve, wherein the drain is selectively activated to remove liquid from the return tank and stop the machine when a module is on the duty/cycle pathway in the return tank and the transfer valve has been activated to remain permanently closed.

15. The method recited in claim 14 wherein the drain is a first drain and the method further comprises the steps of:
locating a stop-valve in the return tank between the upper liquid surface level and the transfer valve to divide the return tank into an upper return tank above the stop-valve and a lower return tank below the stop-valve, wherein the stop-valve establishes a liquid tight barrier across the pathway in the return tank between the upper return tank and the lower return tank when the stop-valve is activated;
providing an air vent located below the stop-valve to allow removing liquid from the lower return tank through the first drain when the stop-valve is activated; and
creating a second drain located in the upper return tank above the stop-valve to allow draining of liquid from the upper return tank when the stop-valve is activated.

16. The method recited in claim 15 further comprising the step of locating a master drain in the transfer tank for removing liquid from the transfer tank.

17. The method recited in claim 16 wherein each module has a same velocity/location profile along the duty-cycle pathway through the bi-level tank, and there are an n number of modules, and wherein the duty cycle of each module is divided into an n number of sequentially equal time segments, and wherein the n^{th} time segment for a particular module is contiguous with the time segment of an n±1 adjacent module.

18. The method as recited in claim 15 wherein the holding step requires a plurality of grips and includes the steps of:
activating a first grip positioned in the upper return tank above the stop-valve to hold a module in the return tank when the stop-valve is activated;
activating a second grip positioned in the upper return tank below the stop-valve and above the transfer valve to hold a module in the return tank when the stop-valve is activated; and
activating a third grip positioned in the transfer tank to hold a module in the transfer tank when the stop-valve is activated.

19. The method recited in claim 12 further comprising the steps of:
introducing liquid into the respective areas where isolated individual modules are held after the draining step;
activating the valve mechanism to reestablish the pathway; and
releasing the modules in accordance with a predetermined release schedule to resume an operation of the machine.

20. The method recited in claim 19 further comprising the step of reorienting modules on the pathway prior to the activating and releasing steps.
